(19) United States
(12) Patent Application Publication
(10) Pub. No.: US 2026/0194815 A1
(43) Pub. Date: Jul. 9, 2026

(54) LITHOGRAPHY METHOD

(71) Applicant: TAIWAN SEMICONDUCTOR MANUFACTURING COMPANY, LTD., Hsinchu (TW)

(72) Inventors: Jia-Lin WEI, Hsinchu City (TW); Lilin CHANG, Taipei City (TW); Yahru CHENG, Taipei (TW)

(73) Assignee: TAIWAN SEMICONDUCTOR MANUFACTURING COMPANY, LTD., Hsinchu (TW)

(21) Appl. No.: 19/009,599

(22) Filed: Jan. 3, 2025

(51) Int. Cl. G03F 7/20; G03F 7/038; G03F 7/039; G03F 7/11; G03F 7/16; G03F 7/38; G03F 7/40

(52) U.S. Cl. CPC G03F 7/2024; G03F 7/038; G03F 7/039; G03F 7/11; G03F 7/162; G03F 7/2004; G03F 7/38; G03F 7/40

(57) ABSTRACT

A lithography method comprises the following steps. A target layer is formed over a substrate. A photoresist layer is formed over the target layer. The photoresist layer is exposed. The photoresist layer is developed using a first developer such that first photoresist layer has a first pitch. The photoresist layer is developed using a second developer different from the first developer. An organic material is formed over the photoresist layer. The organic material and the photoresist layer are etched.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a lithography system for performing various lithography patterning processes constructed according to various aspects of the present disclosure.

FIG. 2 is a schematic view of an exposure module in accordance with some embodiments.

FIGS. 3A and 3B are block diagrams illustrating a method for lithography process flow constructed according to aspects of the present disclosure in one embodiment.

FIGS. 4-8A and 9-12 are cross-sectional views of a semiconductor device in an intermediate stage of fabrication in accordance with some embodiments of the present disclosure.

FIG. 8B shows a chemical reaction of the photoresist layer by treating the photoresist layer to make the photoresist layer insoluble to propylene glycol methyl ether acetate (PGMEA) in accordance with some embodiments.

FIGS. 13-17 are cross-sectional views of a semiconductor device in an intermediate stage of fabrication in accordance with some embodiments of the present disclosure.

FIG. 18A is a perspective view of the semiconductor device in an intermediate stage of fabrication in accordance with some embodiments of the present disclosure.

FIGS. 18B and 18C are cross-sectional views along line a1-a1 and line b1-b1 of FIG. 18A, respectively, in accordance with various aspects of the present disclosure.

FIGS. 19-22 are cross-sectional views of the semiconductor device in an intermediate stage of fabrication in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

“As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.”

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

An intensity log slope (ILS) is derived based on an intensity curve. The intensity curve represents the sensitivity of a wafer pattern to the intensity of energy exposure. Thus, the intensity curve is pattern-dependent. The intensity log slope indicates the change in exposure energy relative to a change in critical dimension of the pattern. Once ILS is derived, a normalized intensity log slope (NILS) is derived for different positions of the wafer pattern that are under evaluation.

IC fabrication processes progress to more advanced technology nodes, such as the 10-nanometer node (or smaller nodes). For tighten pitch with worse ILS for optical, exposed photoresist patterns have undesired roughness and cause worse local critical dimension uniformity (LCDU) and wigging. To realize tightened pitch in the advanced IC fabrication technology nodes, extreme ultraviolet (EUV) lithography is developed. However, EUV masks are expected to be more expensive during the ramp of the technology because of the added cost of the complex mask blank, the use of EUV specific mask tools, and a ramp of yield learning relative to the more mature technologies.

Embodiments of the present disclosure provides a method including using a deep UV (DUV) exposure to replace the EUV exposure for cost saving and can reach the same pitch as the EUV exposure. The method can further include using a directed self-assembly (DSA) material to improve the LCDU, wiggling for low polymer dispersity index (PDI) of co-polymer.

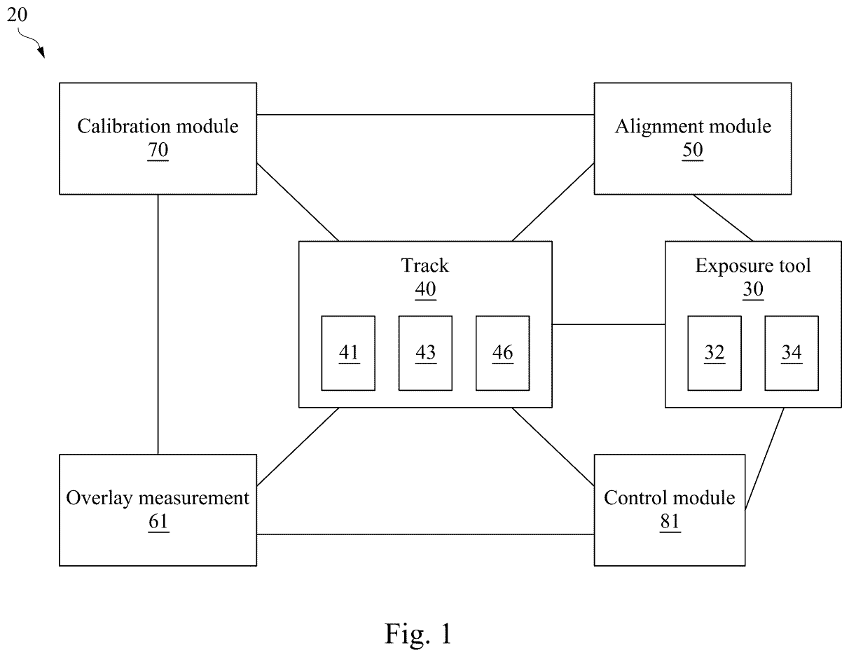

FIG. 1 is a schematic view of a lithography system 20 for performing various lithography patterning processes constructed according to various aspects of the present disclosure. With reference to FIG. 1 and other figures, the lithography system 20 and the method utilizing the same are collectively described. The lithography system 20 includes various processing tools and metrology tools coupled together and configured for performing various lithography processes including coating, alignment, exposure, baking, developing and/or other lithography patterning processes. Therefore, those coupled processing tools and metrology tools are collectively referred to as a lithography system 20. However, each tool of the lithography system 20 may be reconfigured, such as being reconfigured to be coupled with other lithography tools or be a part of another lithography system.

Referring to FIG. 1, the lithography system 20 includes a lithography exposure tool (or exposure tool) 30 designed to perform a lithography exposure process to a radiation-sensitive material layer (e.g., photoresist layer or resist layer). The exposure tool 30 is designed operable to implement a proper mechanism of a lithography process. In one example, an exposure mode is implemented such that the image of a photomask is formed on a wafer by one shot. In another example, a step-and-exposure mode is implemented such that the image of the photomask is repeatedly formed on a plurality field regions of the wafer. In some embodiments, a step-and-scan mode is implemented such that the image of the photomask is repeatedly scanned to a plurality field regions of the wafer. Therefore, the exposure tool 30 is also referred to as a scanner.

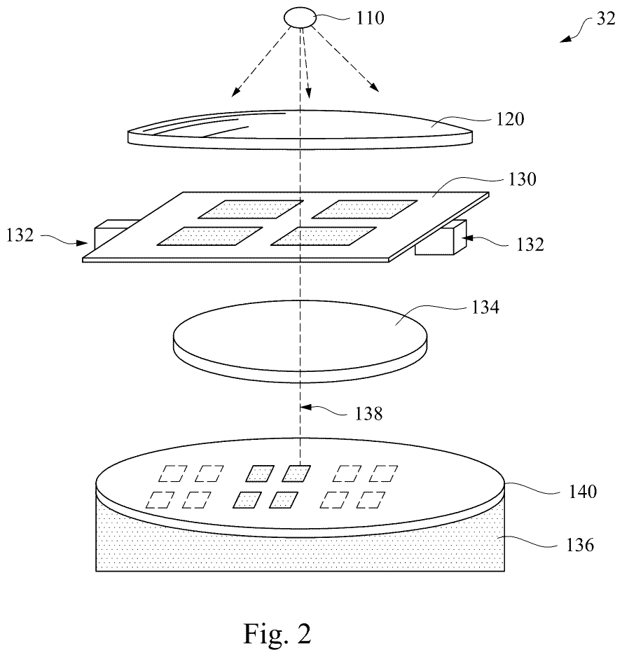

The exposure tool 30 can include an exposure module 32, which is further described with reference to FIG. 2 in a schematic view. FIG. 2 is a schematic view of the exposure module 32 in accordance with some embodiments. Referring to FIG. 2, the exposure module 32 includes a radiation source (or source) 110 to provide radiation energy. In the present embodiments, the radiation source may include a light source of deep UV (DUV) in which the wavelength between about 280 nm to about 190 nm, and is a cost-effective method. For example, the radiation source 110 may be an Argon Fluoride (ArF) excimer laser with a wavelength of 193 nm.

The exposure module 32 also includes an optical subsystem that receives the radiation energy from the radiation source 110, modulates the radiation energy by the image of a photomask and directs the radiation energy to a resist layer coated on an integrated circuit substrate (such as a semiconductor wafer or a wafer). In one embodiment, the optical subsystem is designed to have a refractive mechanism. In this situation, the optical subsystem includes various refractive components, such as lenses.

In an embodiment, the exposure module 32 includes an illumination unit (e.g., a condenser) 120. The illumination unit 120 may include a single lens or a lens module having multiple lenses and/or other lens components. For example, the illumination unit 120 may include microlens arrays, shadow masks, and/or other structures designed to aid in directing radiation energy from the radiation source 110 onto a reticle (also referred to as photomask or mask) 130.

During a lithography exposure process (or exposure process), the photomask (mask or reticle) 130 is positioned in the exposure module 32 such that an integrated circuit pattern defined thereon is imaged on the resist layer. In one embodiment, the reticle 130 includes a transparent substrate and a patterned absorption layer. The transparent substrate may use fused silica (SiO₂) relatively free of defects, such as borosilicate glass and soda-lime glass. The transparent substrate may use calcium fluoride and/or other suitable materials. The patterned absorption layer may be formed using a plurality of processes and a plurality of materials, such as depositing a metal film made with chromium (Cr) and iron oxide, or an inorganic film made with MoSi, ZrSiO, SiN, and/or TiN. A light beam may be partially or completely blocked when directed on an absorption region. The absorption layer may be patterned to have one or more openings through which a light beam may travel without being absorbed by the absorption layer. The mask may incorporate other resolution enhancement techniques such as phase shift mask (PSM) and/or optical proximity correction (OPC).

The reticle 130 is secured on a reticle stage 132 of the exposure module 32 by a clamping mechanism (not shown), such as vacuum clamping or e-chuck clamping. In the present embodiment, the clamping mechanism is a portion of the reticle stage 132. The reticle stage 132 is designed and configured to be operable for translational and rotational motions according to the present embodiment. In another embodiment, the reticle stage 132 is further designed operable to tilt such that the reticle is tilted to (not parallel with) a wafer to be patterned in the exposure module 32.

Still referring to FIG. 2, the exposure module 32 includes a projection unit 134. The projection unit 134 may have a single lens element or a plurality of lens elements configured to provide proper illumination to the resist layer on a wafer. Each lens element may include a transparent substrate and may further include a plurality of coating layers. The transparent substrate may be a conventional projection lens, and may be made of fused silica (SiO₂), calcium-fluoride (CaF₂), lithium fluoride (LiF), barium fluoride (BaF₂), or other suitable material. The materials used for each lens element may be chosen based on the wavelength of light used in the lithography process to minimize absorption and scattering. The illumination unit 120 and the projection unit 134 are collectively referred to as an imaging sub-module. The imaging sub-module may further include additional components such as an entrance pupil and an exit pupil to form an image of the reticle 130 on a wafer to be patterned. In another embodiment, the imaging sub-module may alternatively include various mirror components to provide a reflective mechanism of imaging.

Still referring to FIG. 2, the exposure module 32 further includes a substrate stage 136 that is capable of securing and moving a substrate 140 such that the substrate 140 is aligned with the reticle 130. The substrate 140 is secured on a substrate stage 136 by a clamping mechanism, such as vacuum clamping or e-chuck clamping. In one embodiment, the substrate stage 136 is further designed and configured to be operable for translational and rotational motions according to the present embodiment. In another embodiment, the substrate stage 136 is further designed operable to tilt or dynamically change the tilt angle relative to the optical axis 138 of the exposure module 32 such that the substrate is not perpendicular to the optical axis 138.

In the present example, the substrate 140 is provided in the exposure module 32 for receiving a lithography process. In one embodiment, the substrate 140 is an integrated circuit substrate (IC substrate), such as a semiconductor wafer (or wafer) having an elementary semiconductor such as crystal silicon, polycrystalline silicon, amorphous silicon, germanium, and diamond, a compound semiconductor such as silicon carbide and gallium arsenic, an alloy semiconductor such as SiGe, GaAsP, AlInAs, AlGaAs, and GaInP, or a combination thereof. In furtherance of the present embodiment, a resist layer is coated on the substrate 140 and receives the radiation energy from the radiation source 110 during a lithography exposure process.

Referring back to FIG. 1, the exposure tool 30 further includes an alignment unit 34 integrated with the exposure module 32. Both the exposure module 32 and the alignment unit 34 are integrated together to constitute main modules of the exposure tool 30. In one embodiment, the exposure module 32 and the alignment unit 34 each include a respective substrate stage. In another embodiment, the exposure module 32 and the alignment unit 34 share one substrate stage that is designed and configured operable to move between the alignment unit 34 and the exposure module 32.

Still referring to FIG. 1, the lithography system 20 also includes a lithography track unit (simply track) or a plurality of tracks 40 coupled with the exposure tool 30. The track 40 is a processing tool that integrates resist processing into one tool. The resist processing includes coating, baking and development according to one embodiment. In the present embodiment, the track 40 further includes a coating module 41, a development module 43 and a baking module 46. In another embodiment, the resist processing includes coating, soft-baking, hard-baking and development. In this embodiment, the track 40 may include two or more baking modules designed or configured for baking at different temperatures, respectively. The track 40 is coupled with the exposure tool 30 such that wafers can be exchanged between them.

Still referring to FIG. 1, the lithography system 20 also includes an alignment module 50 configured to be coupled with the exposure tool 30 according to the present disclosure. The alignment module 50 is coupled with the exposure tool 30 such that the wafers through the alignment module 50 are sent to the exposure tool 30 for corresponding steps. Specifically, the alignment module 50 is coupled with the exposure tool 30 such that wafers can be transferred from the alignment module 50 to the exposure tool 30. In one embodiment, the alignment process includes measure the alignment marks relative to a reference structure, such as a virtual grid, to define the alignment error.

Back to FIG. 1, the lithography system 20 includes an overlay measurement tool 61 designed to perform an overlay measurement after the resist layer is patterned. For example, the overlay error is measured between the patterned resist layer and the underlying material layer on the substrate 140. Still referring to FIG. 1, the lithography system 20 includes a calibration module 70 designed for alignment calibration. In one embodiment, the calibration module 70 is designed to stand alone and couple with other tools of the lithography system 20. The calibration module 70 is designed to perform a calibration process among different position units, such as the embedded alignment unit 34 and the position units of the alignment module 50. Referring to FIG. 1, the lithography system 20 may further includes a control module 81 designed for controlling the exposure tool 30 or for controlling other portion of the lithography system 20 to tune various parameters in order to eliminate or reduce the overlay error. In one embodiment, the control module 81 may base on the alignment data from the alignment measurement to perform a tuning process. The lithography system 20 may include other components to be coupled with other tools or components of the lithography system 20 for performing various lithography processes. As noted above, the lithography system 20 in FIG. 1 may be configured differently.

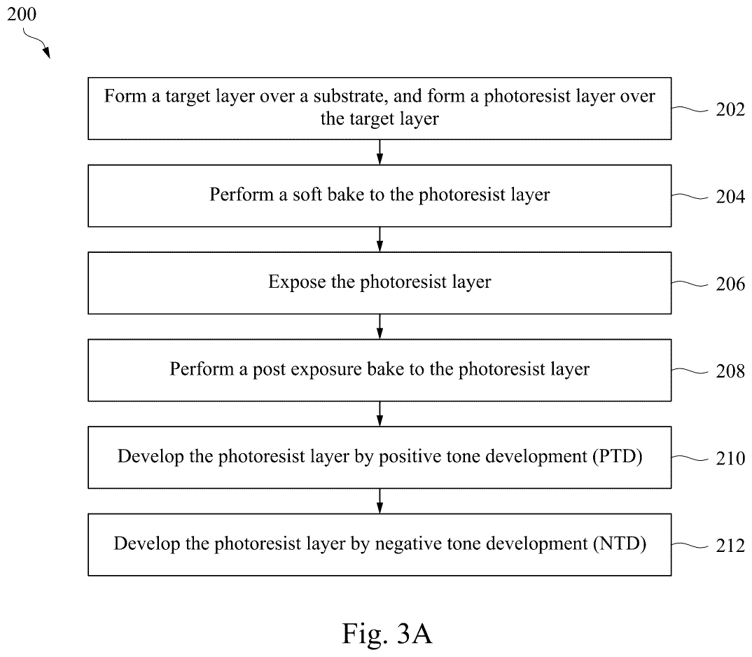

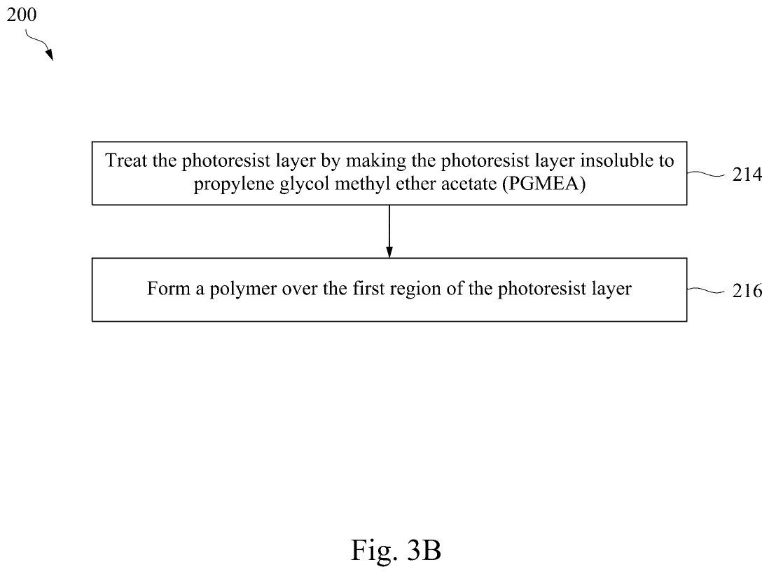

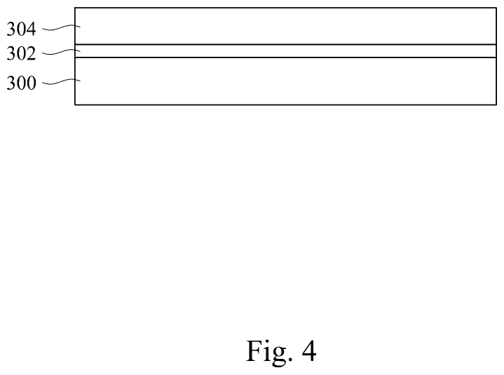

FIGS. 3A and 3B are block diagrams illustrating a method 200 for lithography process flow constructed according to aspects of the present disclosure in one embodiment. The lithography process is implemented by the lithography system 20 of FIG. 1 in the present embodiment. FIGS. 4-8A and 9-12 are cross-sectional views of a semiconductor device in an intermediate stage of fabrication in accordance with some embodiments of the present disclosure.

Referring to FIGS. 3A and 4, the method 200 starts at step 202 in which a target layer 302 is formed over a substrate 300, and a photoresist layer 304 is formed over the target layer 302. In some embodiments, the target layer 302 can be formed by chemical vapor deposition (CVD), physical vapor deposition (PVD), atomic layer deposition (ALD), spin coating or the like. In some embodiments, the photoresist layer 304 may be formed on the target layer by spin coating a photoresist composition. In some embodiments, the photoresist composition can include crosslinkable materials. For example, photoresist composition can include epoxy, double bonds as crosslink sites that are not reactive at subsequent soft bake, exposure, post exposure bake but are reactive to a subsequent high temperature bake in order to undergo a crosslinking reaction for being insoluble to PGMEA.

In some embodiments, the photoresist composition can include a dual tone developable photoresist (or photosensitive polymer) and a solvent in which the dual tone developable photoresist is dissolved in. In some embodiments, the dual tone developable photoresist can include a crosslinker having a formula (a):

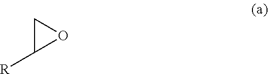

in which R represents a substituted or unsubstituted linear, branched, or cyclic alkyl group having 1 to 20 carbon atoms, or a substituted or unsubstituted aryl group having 6 to 14 carbon atoms. The dual tone developable photoresist can be developed in a positive-tone development (PTD) and in a negative-tone development (NTD). For example, by controlling developable amounts of the dual tone developable photoresist in a positive tone developer in the PTD and in a negative tone developer in the NTD respectively, a contrast for the photoresist layer can be controlled.

Reference is made to FIG. 3A. The method 200 then proceeds to step 204 by performing a soft bake to the photoresist layer 304 in accordance with some embodiments. The photoresist layer 304 is baked at a temperature and time sufficient to cure and dry the photoresist layer 304. The solvent in the photoresist layer 304 can be removed or partially removed by evaporation. In some embodiments, the soft bake can be performed at a bake temperature in a range from about 70° C. to about 150° C., and the dual tone developable photoresist cannot react or crosslink in the soft bake.

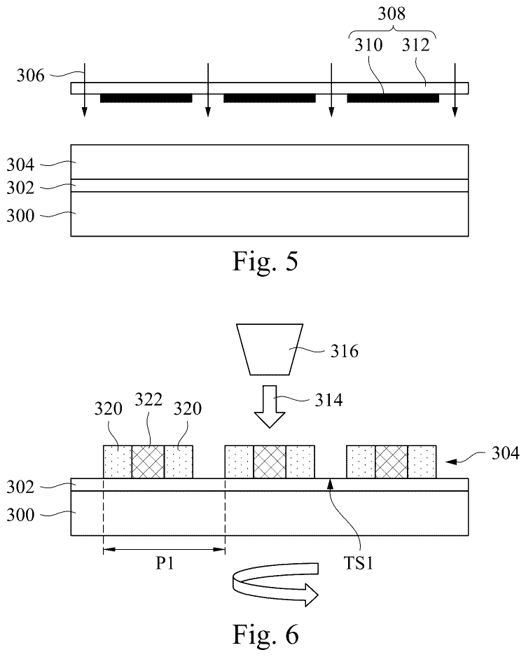

Reference is made to FIGS. 3A and 5. The method 200 then proceeds to step 206 by exposing the photoresist layer 304 to an actinic radiation in accordance with some embodiments. In some embodiments, the photoresist layer 304 can be exposed to ultraviolet radiation. In some embodiments, the ultraviolet radiation is deep ultraviolet radiation (DUV). In some embodiments, exposing the photoresist layer 304 to the actinic radiation is performed without using EUV radiation. As shown in FIG. 5, the actinic radiation 306 passes through a photomask 308 before irradiating the photoresist layer 304 in some embodiments. In some embodiments, the photomask 308 has a pattern to be replicated in the photoresist layer 304. The pattern is formed by an opaque pattern 310 on the photomask substrate 312 in some embodiments. The opaque pattern 312 may be formed by a material opaque to deep ultraviolet radiation, such as chromium, while the photomask substrate 308 is formed of a material that is transparent to ultraviolet radiation, such as fused quartz.

A region of the photoresist layer 304 exposed to the actinic radiation 306 undergoes a chemical reaction thereby changing its solubility in the subsequently applied positive tone developer relative to a region of the photoresist layer 304 not exposed to the actinic radiation 306. In some embodiments, the region of the photoresist layer 304 exposed to the actinic radiation 306 has an increased solubility to the positive tone developer.

Referring back to FIG. 3A, the method 200 then proceeds to step 208 by performing a post exposure bake (PEB). In some embodiments, the PEB can be performed at a bake temperature in a range from about 70° C. to about 150° C., and the dual tone developable photoresist cannot react or crosslink in the PEB. The PEB may be used in order to assist in the generating, dispersing, and reacting of the acid/base/free radical generated from the impingement of the radiation 306 upon the photoresist layer 304 during the exposing the photoresist layer 304. Such assistance helps to create or enhance chemical reactions which generate chemical differences between the exposed region and the unexposed region within the photoresist layer 304. These chemical differences also cause differences in the solubility between the exposed region and the unexposed region.

Referring to FIGS. 3A and 6, the method 200 then proceeds to step 210 by developing the photoresist layer 304 by the positive tone development (PTD). The positive tone developer 314 is supplied from a dispenser 316 to the photoresist layer 304. In some embodiments, the exposed region of the photoresist layer 304 is removed by the positive tone developer 314, forming a first pattern of openings 318 in the photoresist layer 304 to expose a first top surface TS1 of the target layer 302. In some embodiments, after the PTD, the patterned photoresist layer 304 can thus be formed having a first pitch P1 of about 80 nm to about 100 nm, such as about 88 nm.

In some embodiments, the exposed region of the photoresist layer 15 can be hydrophilic and thus can be dissolved by the positive tone developer 314, which is a hydrophilic developer, such as TMAH during the PTD and the unexposed region remain hydrophobic and thus is intact. The unexposed region can include first regions 320 and second regions 322 in which the second regions 322 are semi-dissolving regions which can be soluble to a negative tone photoresist in a subsequent NTD. In some embodiments, the second regions 322 can be on opposite sides of the first regions 320.

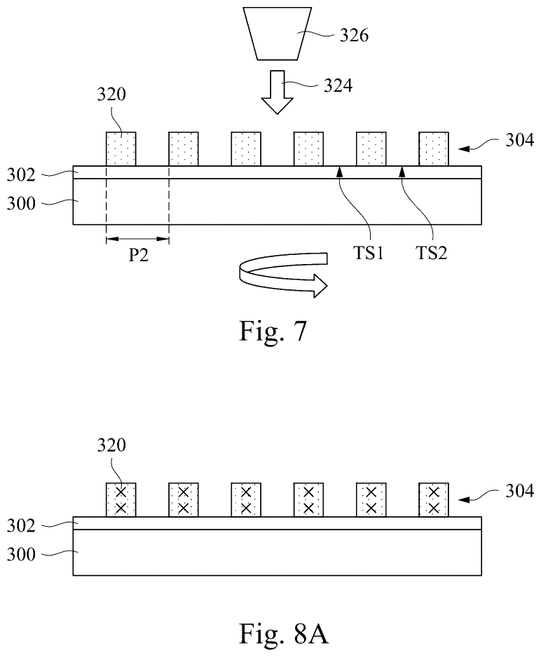

Referring to FIGS. 3A and 7, the method 200 then proceeds to step 212 by developing the photoresist layer 304 by a negative tone development (NTD). As shown in FIG. 7, a second developer 324 is supplied from a dispenser 326 to the photoresist layer 304. In some embodiments, the second regions (semi-dissolving regions) 322 of the photoresist layer 304 is removed by the second developer 324, forming a pattern of openings in the photoresist layer 304 to further expose the target layer 302. In some embodiments, a second top surface TS2 of the target layer 302 is exposed. The second developer 324 can be a hydrophobic developer, such as n-Butyl acetate (nBA). In some embodiments, after the NTD, the photoresist layer 15 can have a first pattern pitch of about 40 nm to about 50 nm, such as about 44 nm.

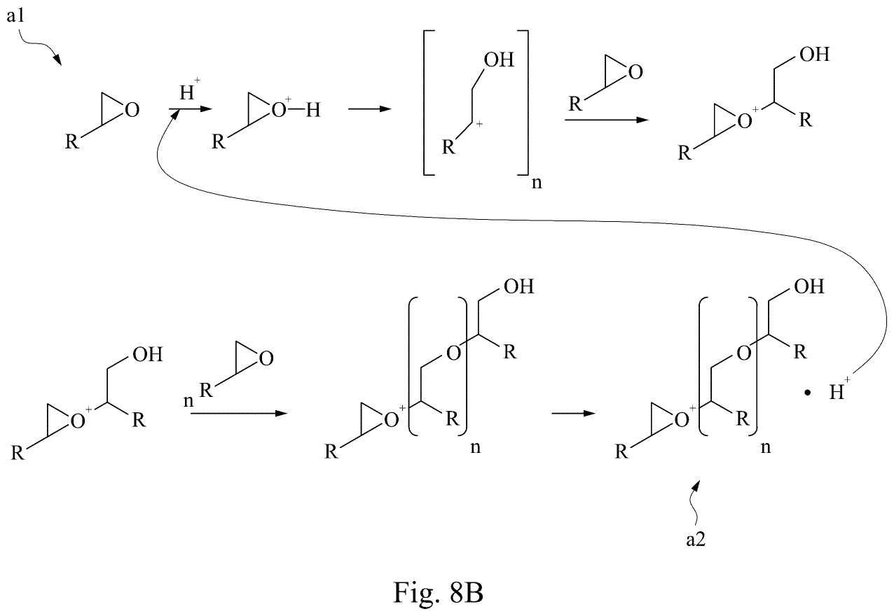

FIG. 8B shows a chemical reaction of the photoresist layer 304 by treating the photoresist layer 304 to make the photoresist layer 304 insoluble to propylene glycol methyl ether acetate (PGMEA) in accordance with some embodiments. Referring to FIGS. 3B, 8A, 8B, the method 200 then proceeds to step 214 by treating the photoresist layer 304 to make the photoresist layer 304 insoluble to propylene glycol methyl ether acetate (PGMEA). For example, treating the photoresist layer can include bake, etch, UV treatment, or a combination thereof, to increase a degree of crosslinking and/or a hardness of the first region of the photoresist layer such that the first regions of the photoresist layer 304 can have an increased PGMEA resistance/insolubility. In some embodiments, the photoresist layer 304 may undergo a chemical reaction R1 in FIG. 8B, resulting a crosslinked structure a2. For example, the crosslinker of the photoresist layer 304 including the epoxy or the formula (a) can be triggered and crosslink the dual tone developable photoresist (or the photosensitive polymer). In other words, the crosslinker can have a crosslink temperature to crosslink the dual tone developable photoresist (or the photosensitive polymer).

In some embodiments where the bake is implemented, the photoresist layer 304 can be treated at a bake temperature greater than or equal to the crosslink temperature of the crosslinker and greater than the bake temperatures at the soft bake in the step 204 and at the PEB in the step 208. In some embodiments, such bake can be performed at a temperature greater than about 150° C. In some embodiments where the etch is implemented, the photoresist can be treated by the etch using dry etching (such as plasma etching, reactive ion etching, etc). For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. In some embodiments where the UV treatment is implemented, the photoresist layer 304 can be exposed to an UV light produced by a UV light source. In some embodiments, the first regions 320 of the photoresist layer can have a thickness large enough for a subsequent DSA patterning.

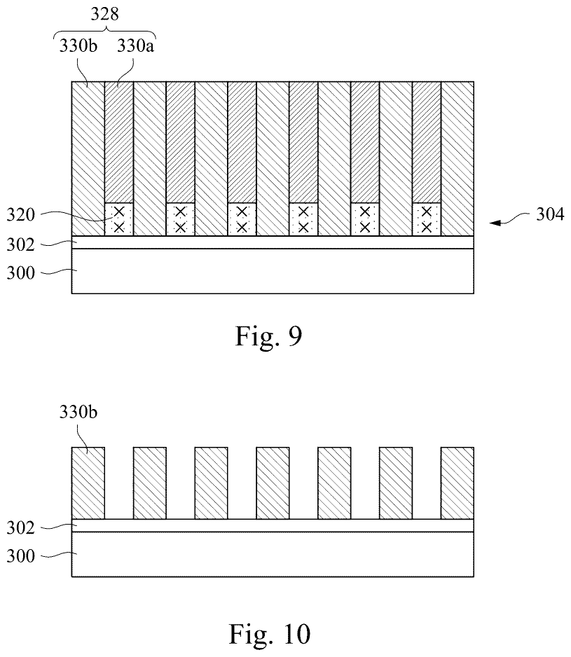

Referring to FIGS. 3B and 9, the method 200 may proceed to operation 216 in which an organic material 328 is formed over the first regions 320 of the photoresist layer 304. In some embodiments, the organic material 328 can be a copolymer which is a directed self-assembly (DSA) material and can be block copolymer materials able to align in regular, repeating patterns, such as spherical, cylindrical, lamellar (layered), and/or bicontinuous gyroid arrangements, in what is termed microphase separation. The morphology of the microphase separated copolymer may depend on the polymers used, the relative amounts of the constituent polymers, process variables including temperature, and other factors. Once a desired morphology is obtained, subsequent fabrication processes may transfer the pattern to the target layer 302. In some embodiments, the copolymers of the DSA material can include a first polymer 330a and a second polymer 330b different from the first polymer 330a. For example, the first polymer 330a and the second polymer 330b have different sensitivities to particular etchants. The first polymer 330a may be removed, and the second polymer 330b may be used as a mask to pattern underlying layers. In some embodiments, the copolymer may include polystyrene-polymethyl methacrylate (PS-PMMA). That is, the first polymer 330a can be PMMA can be aligned to the first regions 320 of the photoresist layer 304 and arranged over the first regions 320. That is, the first polymer 330a can be in contact with (overlap) a top surface of the first regions 320. The second polymer 330b can be PS and can be aligned to the target layer 302. That is, the second polymer 330b can be in contact with (overlap) the target layer 302. Formation of the organic material 328 may include spin coating the organic material 328 on the target layer 302 and the first regions 320 of the photoresist layer 304 and then perform an anneal process to drive the organic material 328 self assembly, leading to the first polymer 330a and the second polymer 330b of FIG. 9. In one such embodiment, with appropriate surface energy conditions, the block copolymers segregate into the first polymer and the second polymer based on the underlying material, that is, the target layer 302. For example, in some embodiments, polystyrene aligns selectively to the target layer 302 in which the target layer 302 includes metal lines (or corresponding metal line cap or hardmask material). Meanwhile, the polymethyl methacrylate aligns selectively to the first region 320 of the photoresist layer 304.

In some embodiments, the organic material 328 further includes a solvent. For example, the solvent can be PGMEA. As discussed previously with regard to FIG. 8A, the first regions 320 of the photoresist layer 304 is insoluble to the PGMEA, and thus can be intact after forming the organic material 328.

Referring to FIGS. 3B and 10, the method 200 may proceed to operation 218 in which the first polymer 330a and the underlying first regions 320 of the photoresist layer 304 can be removed by a wet etch using a suitable solvent. The second polymer 330b exhibits a higher etch resistance to the solvent than the first polymer 330a and the first regions 320 of the photoresist layer 304. In some embodiments, the second polymer 330b can be partially removed during the wet etch and thus have a reduced height. By using the DSA process, a pattern with improved LCDU and wiggling lithography performance can be achieved for low polymer dispersity index (PDI) block copolymer including a PDI in a range from about 1 to about 1.05.

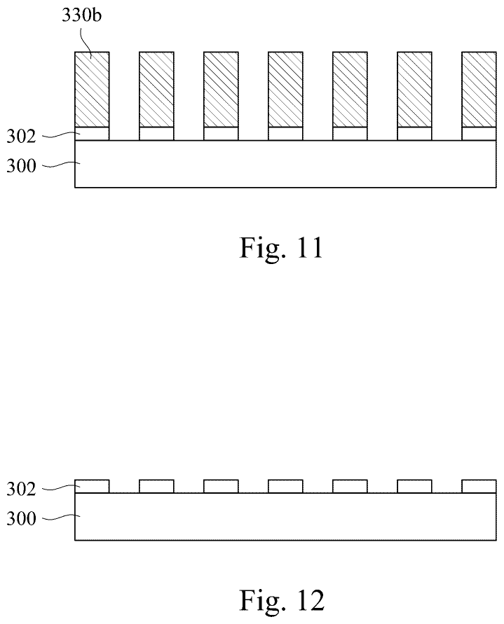

Referring to FIGS. 3B and 11, the method 200 may proceed to operation 220 in which an etch process is performed to the target layer 302 using the second polymer 330b as an etch mask. For example, the etch process is a dry etch process including a biased plasma etch process that uses a chlorine-based chemistry, CF₄, NF₃, SF₆, or the like. The dry etch process may be performed anisotropically. The second polymer 330b is removed after etching the target layer 302 by using a suitable stripper solvent or by an ashing operation. The resulting structure is shown in FIG. 12.

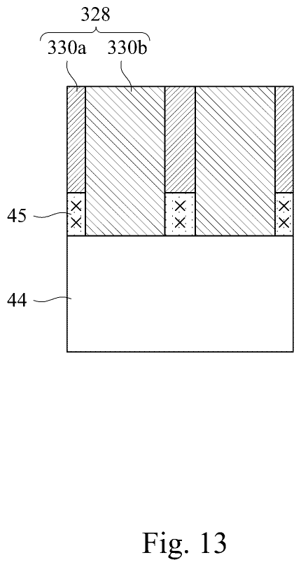

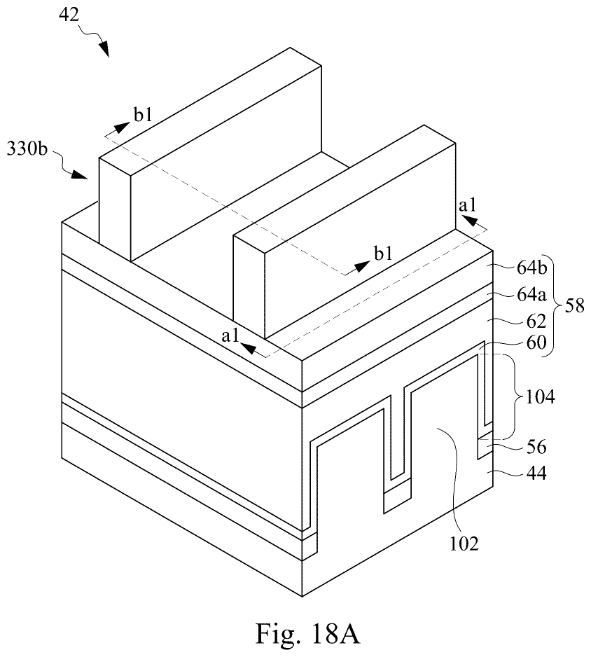

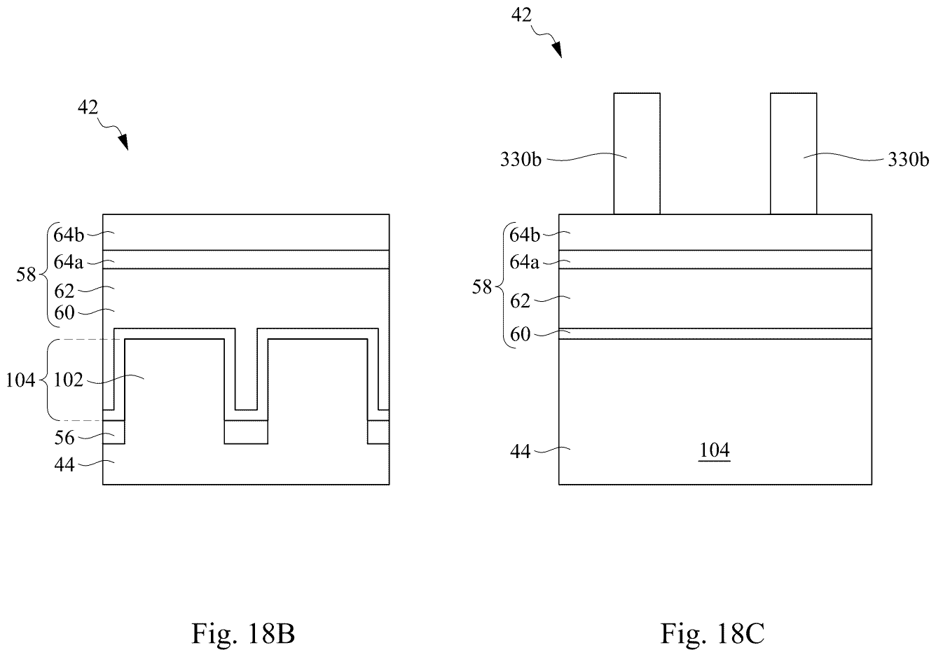

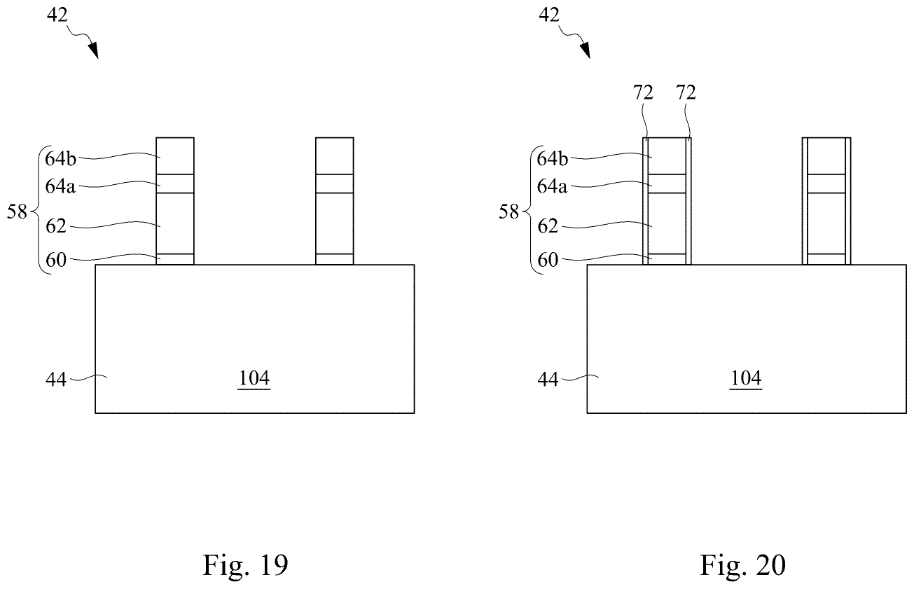

FIGS. 13-17 are cross-sectional views of a semiconductor device 42 in an intermediate stage of fabrication in accordance with some embodiments of the present disclosure. FIG. 18A is a perspective view of the semiconductor device 42 in an intermediate stage of fabrication in accordance with some embodiments of the present disclosure. FIGS. 18B and 18C are cross-sectional views along line a1-a1 and line b1-b1 of FIG. 18A, respectively, in accordance with various aspects of the present disclosure. FIGS. 19-22 are cross-sectional views of the semiconductor device 42 in an intermediate stage of fabrication in accordance with some embodiments of the present disclosure. Reference is made to FIG. 13. A photoresist layer 45 is formed on a substrate 44. An organic material 328 including the first polymer 330a and the second polymer 330b can be formed on the photoresist layer 45 and the substrate 44. The first polymer 330a can be in contact with the photoresist layer 45 and the second polymer 330b can be in contact with the substrate 44. The photoresist layer 45, the organic material 328 including the first polymer 330a and the second polymer 330b and the substrate 44 are similar to the photoresist layer 304, the organic material 328 including the first polymer 330a and the second polymer 330b and the substrate 300 in terms of composition as discussed previously with regard to FIGS. 4 and 9, and thus the description thereof is omitted herein.

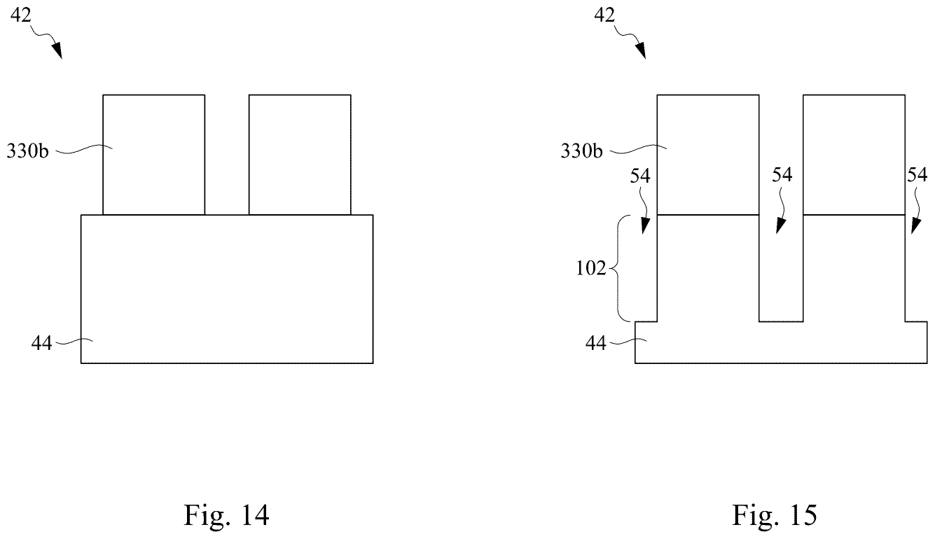

Reference is made to FIG. 13. The first polymer 330a and the underlying photoresist layer 45 can be removed by a wet etch using a suitable solvent, as discussed previously with regard to FIG. 14.

Reference is made to FIG. 15. An etch process is performed to the substrate 44 using the photoresist layer 45 as an etch mask such that trenches 54 are formed in the substrate 44. The etch process may be a dry etch, a wet etch, or a combination thereof.

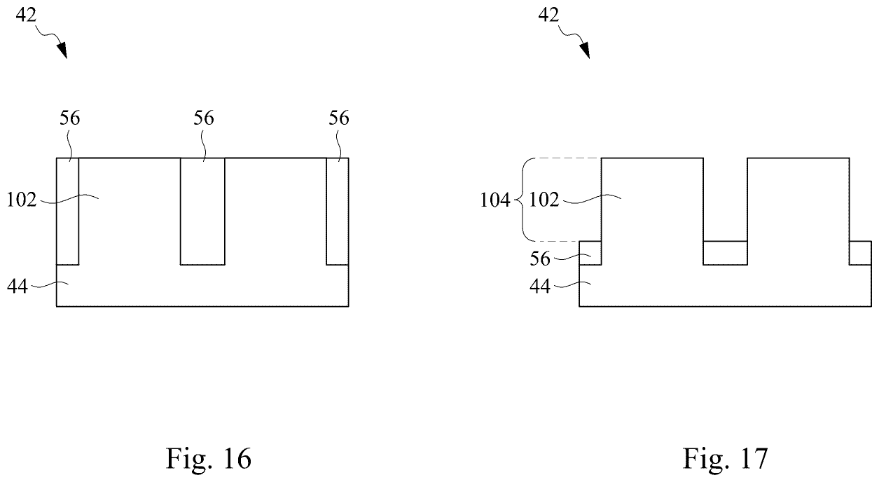

The second polymer 330b is removed after etching the substrate 44 by using a suitable photoresist stripper solvent or by a photoresist ashing operation. Isolation regions such as shallow trench isolation (STI) regions 56 may be formed on the substrate 44, filling into the trenches 54. The resulting structure in shown in FIG. 16.

The STI regions 56 may include a liner oxide (not shown). The liner oxide may be formed of a thermal oxide formed through a thermal oxidation of a surface layer of the substrate 44. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The STI regions 56 may also include a dielectric material over the liner oxide, and the dielectric material may be formed using flowable chemical vapor deposition (FCVD), spin-on coating, or the like.

Referring to FIG. 17, the STI regions 56 are recessed, so that the top portions of semiconductor strips 102 protrude higher than top surfaces of the neighboring STI regions 56 to form protruding fins 104. The etching may be performed using a dry etching process or a wet etching process.

Referring to FIGS. 18A-18C, a dummy gate stack 58 is formed on top surfaces and sidewalls of the protruding fins 104. The dummy gate stack 58 may include a dummy gate dielectric 60 and a dummy gate electrode 62 over the dummy gate dielectric 60. The dummy gate dielectric 60 may be, for example, silicon oxide, silicon nitride, a combination thereof, or the like, and may be deposited or thermally grown according to acceptable techniques. The dummy gate electrode 62 may be deposited over the dummy gate dielectric 60 and then planarized, such as by a chemical mechanical polishing (CMP). The dummy gate electrode 62 may be deposited by PVD, CVD, sputter deposition, or other techniques for depositing the selected material.

The dummy gate dielectric 60 may further include an interfacial layer (not shown) including silicon oxide. The dummy gate electrode 62 may be formed, for example, using polysilicon, and other materials may also be used. The dummy gate electrode 62 may be made of other materials that have a high etching selectivity from the etching of STI regions 56. The dummy gate stack 58 may also include hard mask layers 64a and 64b over the dummy gate electrode 62. The hard mask layers 64a and 64b may be formed of silicon nitride and silicon oxide, respectively. The dummy gate stack 58 may cross over a single one or a plurality of protruding fins 104 and/or STI regions 56. The dummy gate stack 58 also has a lengthwise direction perpendicular to the lengthwise directions of protruding fins 104.

A second polymer 330b is formed over the dummy gate stack 58. In some embodiments, a pad layer (not shown) and a hard mask layer (not shown) may be formed between the second polymer 330b and the dummy gate stack 58. The pad layer and the hard mask layer have an etch selectivity with respect to the second polymer 330b. The pad layer may be a silicon oxide layer and the hard mask layer may be a silicon nitride layer, for example. The above discussion of the operation to form the second polymer 330b in FIGS. 9-10 applies to the second polymer 330b, unless mentioned otherwise.

In FIG. 19, using the second polymer (see FIG. 18C) 330b as a mask, the pattern of the second polymer 330b are extended into the dummy gate stack 58 by etching, using one or more suitable etchants. In some embodiments, the second polymer 330b is removed after etching the dummy gate stack 58 by using a suitable photoresist stripper solvent or by a photoresist ashing operation.

Next, as illustrated in FIG. 20, gate spacers 72 are formed on sidewalls of the dummy gate stack 58. In some embodiments of the gate spacer formation step, a spacer material layer is deposited on the substrate 44 and the dummy gate stack 58. The spacer material layer may be a conformal layer that is subsequently etched back to form gate spacers 72. The gate spacers 72 include one or more dielectric materials such as silicon nitride, silicon oxide, silicon carbide, silicon oxycarbide (SiOC), silicon oxycarbon nitride (SiOCN), other suitable low-k dielectric materials, or combinations thereof. An anisotropic etching process is then performed on the deposited spacer material layer to expose portions of the fins 104 not covered by the dummy gate stack 58 (e.g., in source/drain regions of the fins 104). Portions of the spacer material layer directly above the dummy gate stack 58 may be completely removed by this anisotropic etching process. Portions of the spacer material layer on sidewalls of the dummy gate stack 58 may remain, forming gate spacers, which are denoted as the gate spacers 72, for the sake of simplicity. In some embodiments, the gate spacers 72 may be used to offset subsequently formed doped regions, such as source/drain regions. The gate spacers 72 may further be used for designing or modifying the source/drain region profile.

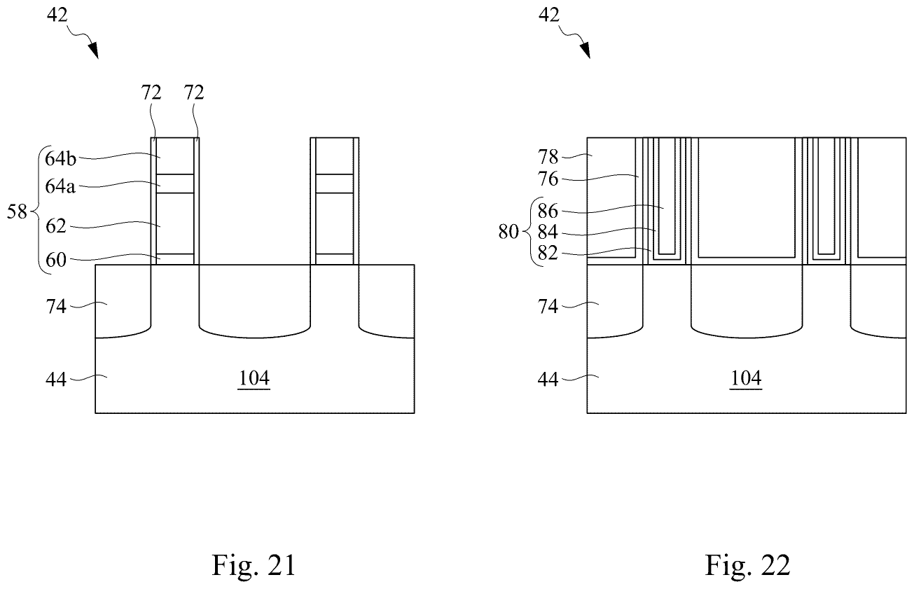

In FIG. 21, after formation of the gate spacers 72 is completed, source/drain epitaxial structures 74 are formed on source/drain regions of the protruding fins 104 that are not covered by the dummy gate stack 58 and the gate spacers 72. In some embodiments, formation of the source/drain epitaxial structures 74 includes recessing source/drain regions of the fins 104, followed by epitaxially growing semiconductor materials in the recessed source/drain regions of the fins 104. The source/drain epitaxial structures 74 are on opposite sides of the dummy gate stack 58.

The source/drain regions of the fins 104 can be recessed using suitable selective etching processing that attacks the fins 104, but hardly attacks the gate spacers 72 and the hard mask layer 64b of the dummy gate stack 58. For example, recessing the fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the protruding fins 104 at a faster etch rate than it etches the gate spacers 72 and the hard mask layer 64b of the dummy gate stack 58. In some other embodiments, recessing the protruding fins 104 may be performed by a wet chemical etch, such as ammonium peroxide mixture (APM), NH₄OH, tetramethylammonium hydroxide (TMAH), combinations thereof, or the like, which etches the fins 104 at a faster etch rate than it etches the gate spacers 72 and the hard mask layer 64b of the dummy gate stack 58. In some other embodiments, recessing the protruding fins 104 may be performed by a combination of a dry chemical etch and a wet chemical etch.

Once recesses are created in the source/drain regions of the fins 104, source/drain epitaxial structures 74 are formed in the source/drain recesses in the fins 104 by using one or more epitaxy or epitaxial (epi) processes that provides one or more epitaxial materials on the protruding fins 104. During the epitaxial growth process, the gate spacers 72 limit the one or more epitaxial materials to source/drain regions in the fins 104. In some embodiments, the lattice constants of the source/drain epitaxial structures 74 are different from the lattice constant of the fins 104, so that the channel region in the fins 104 and between the source/drain epitaxial structures 74 can be strained or stressed by the source/drain epitaxial structures 74 to improve carrier mobility of the semiconductor device and enhance the device performance. The epitaxy processes include CVD deposition techniques (e.g., plasma enhanced chemical vapor deposition (PECVD), vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the fins 104.

In some embodiments, the source/drain epitaxial structures 74 may include Ge, Si, GaAs, AlGaAs, SiGe, GaAsP, SiP, or other suitable material. The source/drain epitaxial structures 74 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 74 are not in-situ doped, an implantation process (i.e., a junction implant process) is performed to dope the source/drain epitaxial structures 74. In some exemplary embodiments, the source/drain epitaxial structures 74 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain epitaxial structures 74 are formed, an annealing process can be performed to activate the p-type dopants or n-type dopants in the source/drain epitaxial structures 74. The annealing process may be, for example, a rapid thermal anneal (RTA), a laser anneal, a millisecond thermal annealing (MSA) process or the like.

Next, in FIG. 22, a contact etch stop layer (CESL) 76 and an interlayer dielectric (ILD) layer 78 are formed on the substrate 44 in sequence. In some examples, the CESL 76 includes a silicon nitride layer, silicon oxide layer, a silicon oxynitride layer, and/or other suitable materials having a different etch selectivity than the ILD layer 78. The CESL 76 may be formed by plasma-enhanced chemical vapor deposition (PECVD) process and/or other suitable deposition or oxidation processes. In some embodiments, the ILD layer 78 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 76. The ILD layer 78 may be deposited by a PECVD process or other suitable deposition technique. In some embodiments, after formation of the ILD layer 78, the wafer may be subject to a high thermal budget process to anneal the ILD layer 78.

In some examples, after forming the ILD layer 78, a planarization process may be performed to remove excessive materials of the ILD layer 78 and the CESL 76. For example, a planarization process includes a chemical mechanical planarization (CMP) process which removes portions of the ILD layer 78 and the CESL 76 overlying the dummy gate stack 58. In some embodiments, the CMP process also removes hard mask layers 64a and 64b (as shown in FIG. 17) and exposes the dummy gate electrode 62.

An etching process is performed to remove the dummy gate electrode 62 and the dummy gate dielectric 60, resulting in gate trenches between corresponding gate spacers 72. The dummy gate stack 58 are removed using a selective etching process (e.g., selective dry etching, selective wet etching, or a combination thereof) that etches materials in the dummy gate stack 58 at a faster etch rate than it etches other materials (e.g., gate spacers 72 and/or the ILD layer 78).

Thereafter, replacement gate structures 80 are respectively formed in the gate trenches. The gate structures 80 may be the final gates of FinFETs. In FinFETs, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. The final gate structures each may be a high-k/metal gate (HKMG) stack, however other compositions are possible. In some embodiments, each of the gate structures 80 forms the gate associated with the three-sides of the channel region provided by the fin 104. Stated another way, each of the gate structures 80 wraps around the fin 104 on three sides. In various embodiments, the high-k/metal gate structure 80 includes a gate dielectric layer 82 lining the gate trench, a work function metal layer 84 formed over the gate dielectric layer 82, and a fill metal 86 formed over the work function metal layer 84 and filling a remainder of gate trenches. The gate dielectric layer 82 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (~3.9). The work function metal layer 84 and/or the fill metal 86 used within high-k/metal gate structures 80 may include a metal, metal alloy, or metal silicide. Formation of the high-k/metal gate structures 80 may include multiple deposition processes to form various gate materials, one or more liner layers, and one or more CMP processes to remove excessive gate materials.

In some embodiments, the interfacial layer of the gate dielectric layer 82 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 82 may include hafnium oxide (HfO₂). Alternatively, the gate dielectric layer 82 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 84 may include work function metals to provide a suitable work function for the high-k/metal gate structures 80. For an n-type FinFET, the work function metal layer 84 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type FinFET, the work function metal layer 84 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal 86 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, the semiconductor device 42 includes other layers or features not specifically illustrated. In some embodiments, back end of line (BEOL) processes are performed on the semiconductor device 42. In some embodiments, the semiconductor device 42 is formed by a non-replacement metal gate process or a gate-first process.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that using the DSA patterning process, the pattern can include an improved LCDU and wiggling lithography performance for the copolymer with low PDI. Another advantage is that by using the DUV exposure to replace EUV exposure, cost saving is achieved and the same pitch as the EUV exposure is reached.

In some embodiments, a lithography method comprises the following steps. A target layer is formed over a substrate. A photoresist layer is formed over the target layer. The photoresist layer is exposed. The photoresist layer is developed using a first developer such that first photoresist layer has a first pitch. The photoresist layer is developed using a second developer different from the first developer. An organic material is formed over the photoresist layer. The organic material and the photoresist layer are etched. In some embodiments, the first developer is a positive tone developer. In some embodiments, the second developer is a negative tone developer. In some embodiments, the organic material is a directed self-assembly (DSA) material. In some embodiments, the lithography method further comprises after developing the photoresist layer, baking the photoresist layer. In some embodiments, the lithography method further comprises after developing the photoresist layer, dry etch the photoresist layer. In some embodiments, the lithography method further comprises after developing the photoresist layer, exposing the photoresist layer to a radiation. In some embodiments, the radiation is UV light. In some embodiments, exposing the photoresist layer is performed using a deep ultraviolet radiation (DUV).

In some embodiments, a lithography method comprises the following steps. A target layer is formed over a substrate. A patterned photoresist layer is formed over the target layer. An organic material is formed over the patterned photoresist layer and the target layer, wherein the organic material comprises a first polymer and a second polymer different from the first polymer, the first polymer is over the patterned photoresist layer, and the second polymer is over the target layer. The first polymer and the patterned photoresist layer are removed. The target layer is etched using the second polymer as an etch mask. In some embodiments, the first polymer comprises polymethyl methacrylate. In some embodiments, the second polymer comprises polystyrene. In some embodiments, the organic material further comprises propylene glycol methyl ether acetate (PGMEA). In some embodiments, the patterned photoresist layer is insoluble to propylene glycol methyl ether acetate (PGMEA). In some embodiments, forming the patterned photoresist layer over the target layer is performed without using extreme ultraviolet radiation.

In some embodiments, a lithography method comprises the following steps. A target layer is formed over a substrate. A photoresist composition is spin coated over the target layer to form a photoresist layer, wherein the photoresist composition comprises a photosensitive polymer and a crosslinker, the crosslinker has a crosslink temperature to crosslink the photosensitive polymer. The photoresist layer is exposed. The photoresist layer is developed. A crosslinking density of the photoresist layer is increased through baking the photoresist layer at a first bake temperature greater than or equal to the crosslink temperature, performing a UV treatment to the photoresist layer or etching the photoresist layer. An organic material is formed over the photoresist layer. The organic material and the photoresist layer are etched. In some embodiments, the crosslinker comprises epoxy, double bond, or a combination thereof. In some embodiments, the method further comprises prior to exposing the photoresist layer, baking the photoresist layer at a second bake temperature, wherein the second bake temperature is lower than the first bake temperature. In some embodiments, the method further comprises prior to developing the photoresist layer, baking the photoresist layer at a third bake temperature, wherein the third bake temperature is lower than the first bake temperature. In some embodiments, the photoresist layer is a dual tone developable photoresist layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A lithography method, comprising:
forming a target layer over a substrate;
forming a photoresist layer over the target layer;
exposing the photoresist layer;
developing the photoresist layer using a first developer such that first photoresist layer has a first pitch;
developing the photoresist layer using a second developer different from the first developer;
forming an organic material over the photoresist layer; and
etching the organic material and the photoresist layer.

2. The lithography method of claim 1, wherein the first developer is a positive tone developer.

3. The lithography method of claim 1, wherein the second developer is a negative tone developer.

4. The lithography method of claim 1, wherein the organic material is a directed self-assembly (DSA) material.

5. The lithography method of claim 1, further comprising:
after developing the photoresist layer, baking the photoresist layer.

6. The lithography method of claim 1, further comprising:
after developing the photoresist layer, dry etch the photoresist layer.

7. The lithography method of claim 1, further comprising:
after developing the photoresist layer, exposing the photoresist layer to a radiation.

8. The lithography method of claim 7, wherein the radiation is UV light.

9. The lithography method of claim 7, wherein exposing the photoresist layer is performed using a deep ultraviolet radiation (DUV).

10. A lithography method, comprising:
forming a target layer over a substrate;
forming a patterned photoresist layer over the target layer;
forming an organic material over the patterned photoresist layer and the target layer, wherein the organic material comprises a first polymer and a second polymer different from the first polymer, the first polymer is over the patterned photoresist layer, and the second polymer is over the target layer;
removing the first polymer and the patterned photoresist layer; and
etching the target layer using the second polymer as an etch mask.

11. The lithography method of claim 10, wherein the first polymer comprises polymethyl methacrylate.

12. The lithography method of claim 10, wherein the second polymer comprises polystyrene.

13. The lithography method of claim 10, wherein the organic material further comprises propylene glycol methyl ether acetate (PGMEA).

14. The lithography method of claim 10, wherein the patterned photoresist layer is insoluble to propylene glycol methyl ether acetate (PGMEA).

15. The lithography method of claim 10, wherein forming the patterned photoresist layer over the target layer is performed without using extreme ultraviolet radiation.

16. A lithography method, comprising:
forming a target layer over a substrate;
spin coating a photoresist composition over the target layer to form a photoresist layer, wherein the photoresist composition comprises a photosensitive polymer and a crosslinker, the crosslinker has a crosslink temperature to crosslink the photosensitive polymer;
exposing the photoresist layer;
developing the photoresist layer;
increasing a crosslinking density of the photoresist layer through baking the photoresist layer at a first bake temperature greater than or equal to the crosslink temperature, performing a UV treatment to the photoresist layer or etching the photoresist layer;
forming an organic material over the photoresist layer; and
etching the organic material and the photoresist layer.

17. The lithography method of claim 16, wherein the crosslinker comprises epoxy, double bond, or a combination thereof.

18. The lithography method of claim 16, further comprising:
prior to exposing the photoresist layer, baking the photoresist layer at a second bake temperature, wherein the second bake temperature is lower than the first bake temperature.

19. The lithography method of claim 16, further comprising:
prior to developing the photoresist layer, baking the photoresist layer at a third bake temperature, wherein the third bake temperature is lower than the first bake temperature.

20. The lithography method of claim 16, wherein the photoresist layer is a dual tone developable photoresist layer.
